(19) United States
(12) Patent Application Publication
(10) Pub. No.: US 2025/0149310 A1
(43) Pub. Date: May 8, 2025

(54) MEMBER FOR SEMICONDUCTOR MANUFACTURING APPARATUS

(71) Applicant: NGK INSULATORS, LTD., Nagoya-City (JP)

(72) Inventors: Hiroshi TAKEBAYASHI, Handa-City (JP); Jyunya WAKI, Handa-City (JP)

(73) Assignee: NGK INSULATORS, LTD., Nagoya-City (JP)

(21) Appl. No.: 18/675,260

(22) Filed: May 28, 2024

Related U.S. Application Data
(63) Continuation of application No. PCT/JP2023/039550, filed on Nov. 2, 2023.

(51) Int. Cl. H01J 37/32; H01L 21/683

(52) U.S. Cl. CPC H01J 37/32724; H01J 37/32568; H01J 37/32577; H01L 21/6833; H01J 2237/2001; H01J 2237/2007

(57) ABSTRACT

A member for semiconductor manufacturing apparatus includes a ceramic plate having a wafer placement surface on its upper surface and a built-in electrostatic electrode; a base plate provided on a lower surface of the ceramic plate; a passage provided from a lower surface of the base plate to the wafer placement surface of the ceramic plate; an internal electrode provided inside the ceramic plate so as to be located in a periphery of the passage under the electrostatic electrode; a switcher coupled to the internal electrode, and configured to switch between whether the internal electrode is electrically coupled to the electrostatic electrode; and a bias electrode provided at a height lower than or equal to a height of the internal electrode electrically independently from the electrostatic electrode, and configured to receive application of a bias voltage when plasma is generated over the wafer placement surface.

### BACKGROUND OF THE INVENTION

### 1. Field of the Invention

The present invention relates to a member for semiconductor manufacturing apparatus.

### 2. Description of the Related Art

Conventionally, members for semiconductor manufacturing apparatus have been known which include: a ceramic plate having a wafer placement surface on its upper surface and a built-in electrode; a base plate provided on the lower surface of the ceramic plate; and a gas passage provided from the lower surface of the base plate to the wafer placement surface of the ceramic plate. In PTL 1, such a member for semiconductor manufacturing apparatus is provided with a cylindrical shield electrode around the gas passage of the ceramic plates. The cylindrical shield electrode has a function of shielding the internal space of the gas passage from the effect of an electric field generated around an electrostatic electrode due to application of a direct-current voltage to the electrostatic electrode. Thus, occurrence of abnormal electrical discharge in the gas passage is prevented or reduced.

### CITATION LIST

### Patent Literature

PTL 1: WO 2023/095707 A1

### SUMMARY OF THE INVENTION

However, in PTL 1, when the shielding by the shield electrode is insufficient, occurrence of abnormal electrical discharge in the gas passage may not be prevented.

The present invention has been devised to solve the above-mentioned problem, and it is a main object to prevent or reduce occurrence of abnormal electrical discharge in a passage by a principle different from a conventional one.

[1] The member for semiconductor manufacturing apparatus of the present invention includes: a ceramic plate having a wafer placement surface on its upper surface and a built-in electrostatic electrode; a base plate provided on a lower surface of the ceramic plate, and configured to include a built-in refrigerant flow path; a passage provided from a lower surface of the base plate to the wafer placement surface of the ceramic plate; an internal electrode provided inside the ceramic plate so as to be located in a periphery of the passage under the electrostatic electrode and not to be exposed to an inner wall of the passage; a switcher coupled to the internal electrode, and configured to switch between whether the internal electrode is electrically coupled to the electrostatic electrode; and a bias electrode provided at a height lower than or equal to a height of the internal electrode electrically independently from the electrostatic electrode, and configured to receive application of a bias voltage when plasma is generated over the wafer placement surface.

In the member for semiconductor manufacturing apparatus, the internal electrode is provided inside the ceramic plate so as to be located in the periphery of each passage under the electrostatic electrode, and not to be exposed to the inner walls of the passages. The switcher is coupled to the internal electrode, and it is possible to switch between whether the internal electrode is electrically coupled to the electrostatic electrode. When a direct-current voltage is applied to the electrostatic electrode, and a bias voltage is applied to the bias electrode, an electric potential gradient occurs in a vertical direction in the internal space of the passages. In the present invention, the internal electrode provided under the electrostatic electrode is electrically coupled to the electrostatic electrode to be equipotential with the electrostatic electrode, thus the vertical distance over which an electric potential gradient occurs can be reduced, as compared to when the internal electrode cannot be electrically coupled to the electrostatic electrode. As a result, even if electrons ionized from the atoms or molecules of a heat transfer gas are accelerated by an electric potential gradient, the electrons are not sufficiently accelerated, and don't receive sufficient energy, thus arc discharge can be avoided. Therefore, it is possible to prevent or reduce occurrence of abnormal electrical discharge in the passages by a principle different from a conventional one by which the effect of an electric field generated around the electrostatic electrode is shielded. In addition, in the present invention, when the internal electrode does not need to have the same potential as the electrostatic electrode, such as when plasma is not generated or when a bias voltage is not applied, the internal electrode can be used for another application by switching the connection destination thereof.

In the present description, “upper”, “lower” do not represent absolute positional relationship, but represent relative positional relationship. Thus, depending on the orientation of the member for semiconductor manufacturing apparatus, “upper” and “lower” may indicate “lower” and “upper”, “left” and “right”, or “front” and “back”. As the “passage”, e.g., a gas passage and a lift pin hole may be mentioned.

[2] In the member for semiconductor manufacturing apparatus (the member for semiconductor manufacturing apparatus according to [1]) of the present invention, the internal electrode may be a heater electrode to be coupled to a heater power supply to generate heat, and the switcher may be configured to switch between whether the heater electrode is electrically coupled to the electrostatic electrode or the heater power supply. In this setting, when the internal electrode does not need to have the same potential as the electrostatic electrode, the internal electrode can be used as a heater by switching the connection destination of the internal electrode to the heater power supply. Thus, e.g., a wafer placed on the wafer placement surface can be maintained at or increased to a desired temperature.

[3] In the member for semiconductor manufacturing apparatus (the member for semiconductor manufacturing apparatus according to [2]) of the present invention, the heater electrode may be wired from one of a pair of terminals to the other of the pair of terminals, and in a periphery of the passage, the heater electrode may be located surrounding the passage, branched and merged.

[4] In the member for semiconductor manufacturing apparatus (the member for semiconductor manufacturing apparatus according to [3]) of the present invention, the heater electrode may form a parallel circuit in the periphery of the passage.

[5] In the member for semiconductor manufacturing apparatus (the member for semiconductor manufacturing apparatus according to any one of [1] to [4]) of the present invention, the base plate may also serve as the bias electrode. In this setting, a bias electrode does not need to be provided separately from the base plate.

[6] In the member for semiconductor manufacturing apparatus (the member for semiconductor manufacturing apparatus according to any one of [1] to [5]) of the present invention, the bias electrode may be built in the ceramic plate.

[7] In the member for semiconductor manufacturing apparatus (the member for semiconductor manufacturing apparatus according to any one of [1] to [6]) of the present invention, the passage may be coupled to a supply source of heat transfer gas. In this setting, in the internal space of the passage, the following phenomenon is likely to occur: the atoms or molecules of a heat transfer gas are ionized to produce electrons which collide with other atoms or molecules, therefore, the significance of application of the present invention is high.

[8] In the member for semiconductor manufacturing apparatus (the member for semiconductor manufacturing apparatus according to any one of [1] to [7]) of the present invention, the base plate may also serve as a source electrode that, when plasma is generated over the wafer placement surface, receives application of a source voltage. In this setting, a source electrode does not need to be provided separately from the base plate.

### BRIEF DESCRIPTION OF THE DRAWINGS

FIG. 1 is a plan view of a wafer placement table 10.

FIG. 2 is a perspective view of the wafer placement table 10 with a cross-sectional view.

FIG. 3 is a partial cross-sectional view of the wafer placement table 10.

FIG. 4 is a cross-sectional view obtained by cutting the wafer placement table 10 by a plane including an electrostatic electrode 22.

FIG. 5 is a cross-sectional view obtained by cutting the wafer placement table 10 by a plane including a heater electrode 30.

FIG. 6 is a partial cross-sectional view of another embodiment.

### DETAILED DESCRIPTION OF THE INVENTION

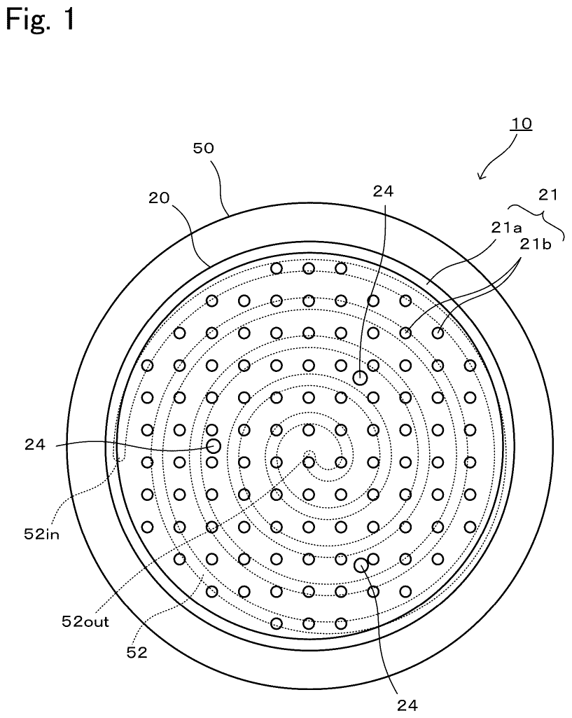

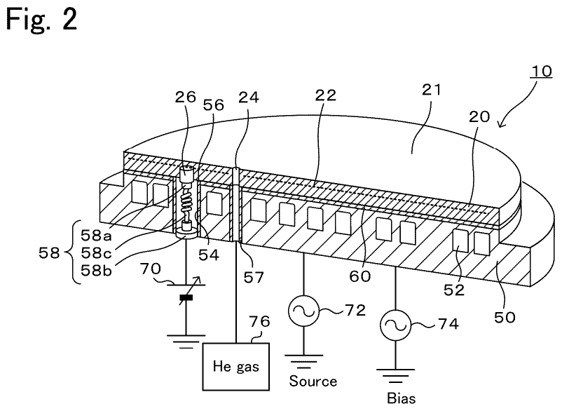

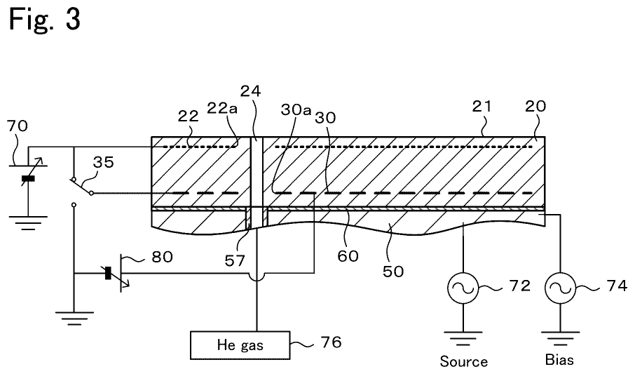

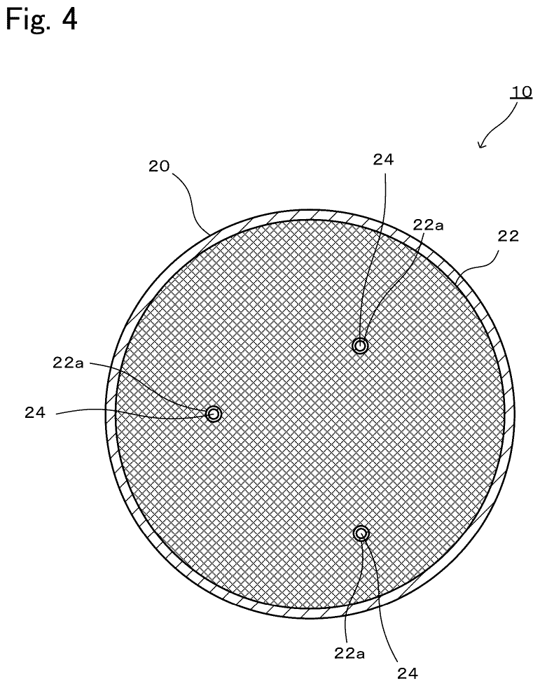

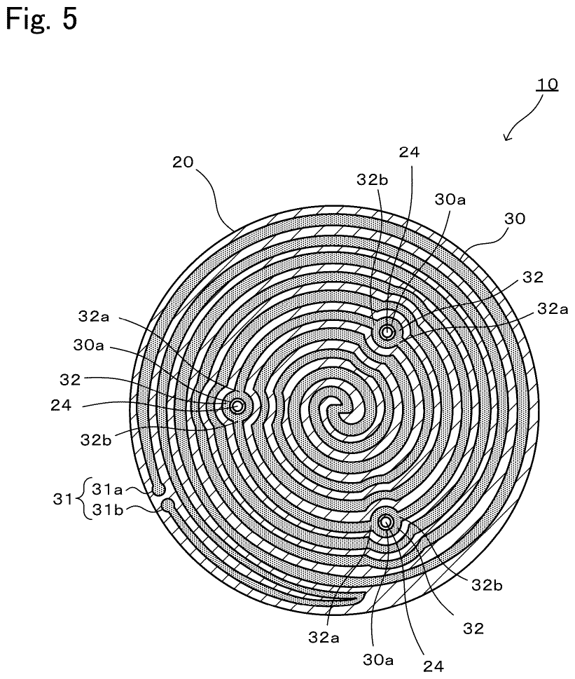

A preferred embodiment of the present invention will be described with reference to the drawings. FIG. 1 is a plan view of a wafer placement table 10, FIG. 2 is a perspective view of the wafer placement table 10 with a cross-sectional view, FIG. 3 is a partial cross-sectional view of the wafer placement table 10, FIG. 4 is a cross-sectional view obtained by cutting the wafer placement table 10 by a plane including an electrostatic electrode 22, and FIG. 5 is a cross-sectional view obtained by cutting the wafer placement table 10 by a plane including a heater electrode 30. Note that in FIG. 2 and FIG. 3, a seal band 21a and circular small projections 21b are omitted. In FIG. 2, the heater electrode 30 is omitted, and in FIG. 3, an electrode terminal 26, a power supply member 58, a power supply member arrangement hole 54 are omitted.

The wafer placement table 10 is an example of a member for semiconductor manufacturing apparatus of the present invention, and as illustrated in FIG. 2, includes a ceramic plate 20, a base plate 50, a bonding layer 60, a power supply member arrangement hole 54, and a gas passage 24.

The ceramic plate 20 is a ceramic circular disk (e.g., a diameter of 300 mm, a thickness of 5 mm) such as an alumina sintered body or an aluminum nitride sintered body. The upper surface of the ceramic plate 20 is a wafer placement surface 21. The ceramic plate 20 has a built-in electrostatic electrode 22. As illustrated in FIG. 1, on the wafer placement surface 21, a seal band 21a is formed along the outer edge, and a plurality of small circular projections 21b are formed on the entire inner surface of the seal band 21a. The seal band 21a and the small circular projections 21b have the same height which is e.g., several μm to several 10 μm. The electrostatic electrode 22 is a circular planar mesh electrode, and coupled to a direct-current power supply 70 via a power supply member 58. When a direct-current voltage is applied to the electrostatic electrode 22, the wafer W is attracted and fixed to the wafer placement surface 21 (specifically, the upper surface of the seal band 21a and the upper surface of the small circular projections 21b) by an electrostatic attraction force, and when the application of the direct-current voltage is stopped, the attraction and fixing of the wafer W to the wafer placement surface 21 is released.

As illustrated in FIG. 3 and FIG. 5, the inside of the ceramic plate 20 is provided with a heater electrode 30. The heater electrode 30 corresponds to an internal electrode of the present invention, and is provided under the electrostatic electrode 22. The heater electrode 30 is provided inside the ceramic plate 20 so as to be located in the periphery of the gas passage 24 to surround the gas passage 24, and not to be exposed to the inner wall of the gas passage 24. Specifically, as illustrated in FIG. 5, the heater electrode 30 is wired from one terminal 31a of a pair of terminals 31 provided on the outer circumference of the ceramic plate 20 to the other terminal 31b of the pair of terminals 31 provided on the outer circumference of the ceramic plate 20 through substantially the entire area of the ceramic plate 20. In the periphery of each gas passage 24, the heater electrode 30 has a parallel section 32 connected in parallel between a branch point 32a and a merge point 32b where the gas passage 24 is branched and merged so as to be located around the gas passage 24 to surround the gas passage 24. The heater electrode 30 is comprised of e.g., a resistance heating element, and is coupled to a heater power supply 80 serving as a direct-current power supply, and generates heat. The resistance heating element may have high melting point metal or its carbide as a main component. As the high melting point metal, e.g., tungsten, molybdenum, tantalum, platinum, rhenium, hafnium and their alloy may be mentioned. As a carbide of high melting point metal, e.g., tungsten carbide and molybdenum carbide may be mentioned. The heater electrode 30 may have a ribbon shape (flat and elongated shape). A ribbon-shaped heater electrode 30 may be formed by printing a paste containing high melting point metal or its carbide. The paste may contain ceramic. The heater electrode 30 may have a coil shape.

A switcher 35 is coupled to the heater electrode 30. The switcher 35 is configured to switch between whether the heater electrode 30 is electrically coupled to the electrostatic electrode 22. Herein, the switcher 35 has a single pole double throw (SPDT) switch, and is configured to switch between whether the heater electrode 30 is electrically coupled to the electrostatic electrode 22 or the heater power supply 80. When the heater electrode 30 is electrically coupled to the electrostatic electrode 22, the heater electrode 30 has the same potential as the electrostatic electrode 22, and serves as an electric potential gradient adjustment electrode that adjusts the electric potential gradient in the gas passage 24. When the heater electrode 30 is electrically coupled to the heater power supply 80, the heater electrode 30 generates heat, and serves as a heater electrode. Note that when the heater electrode 30 is coupled to the heater power supply 80, the heater electrode 30 is coupled thereto so that the heater power supply 80 and the ground (GND) form a closed circuit.

The base plate 50 is a circular disk (e.g., a circular disk with a diameter equal to or greater than the diameter of the ceramic plate 20, and a thickness of 25 mm) having good electrical conductivity and thermal conductivity, and is electrically independent from the electrostatic electrode 22 and the heater electrode 30. The inside of the base plate 50 is provided with a refrigerant flow path 52 through which a refrigerant is circulated. The refrigerant which flows through the refrigerant flow path 52 is preferably liquid, and preferably has electrical insulating properties. As the liquid having electrical insulating properties, e.g., fluorine-based inert liquid may be mentioned. As illustrated in FIG. 1, the refrigerant flow path 52 is formed from one end (inlet 52in) to the other end (outlet 52out) in a swirl shape in a one-stroke pattern over the entirety of the base plate 50 in a plan view. The inlet 52in and the outlet 52out of the refrigerant flow path 52 are respectively coupled to a supply port and a collection port of an external refrigerant device which is not illustrated. The refrigerant supplied from the supply port of the external refrigerant device to the inlet 52in of the refrigerant flow path 52 passes through the refrigerant flow path 52, then returns from the outlet 52out of the refrigerant flow path 52 to the collection port of the external refrigerant device, undergoes temperature control, and is supplied again from the supply port to the inlet 52in of the refrigerant flow path 52. The base plate 50 is coupled to a source power supply 72 and a bias power supply 74. The source power supply 72 is a power supply that generates source RF to produce a plasma over the wafer placement surface 21. The bias power supply 74 is a power supply that generates bias RF to attract ions to the wafer W. The bias RF has a lower frequency and a larger amplitude than the source RF. The bias RF may have sine wave (positive and negative appear alternately), or may have rectangular wave (negative rectangle appears periodically); however, rectangular wave is preferable for sharp etching. The frequency of the source RF is e.g., several 10 to several 100 MHz, and the frequency of the bias RF is e.g., several 100 kHz.

As the material for the base plate 50, e.g., a metal material and a composite material of metal and ceramic may be mentioned. As the metal material, Al, Ti, Mo or an alloy thereof may be mentioned. As the composite material of metal and ceramic, a metal matrix composite material (MMC) and a ceramic matrix composite material (CMC) may be mentioned. As a specific example of such a composite material, a material containing Si, SiC and Ti (also referred to as SiSiCTi), a material obtained by impregnating a SiC porous body with Al and/or Si, and a composite material of Al₂O₃ and TiC may be mentioned. As the material for the base plate 50, a material having a coefficient of thermal expansion closer to that of the material for the ceramic plate 20 is preferably selected.

The bonding layer 60 is a metal bonding layer herein, and bonds the lower surface of the ceramic plate 20 and the upper surface of the base plate 50 together. The metal bonding layer may be a layer composed of e.g., solder or a metal brazing material. The metal bonding layer is formed by e.g., TCB (Thermal compression bonding). The TCB is a publicly known method by which a metal bonding material is inserted between two members to be bonded, and the two members are pressurized and bonded with the two members heated at a temperature lower than or equal to the solidus temperature of the metal bonding material. Note that the bonding layer 60 may be a resin adhesive layer. As the material for the resin adhesive layer, e.g., an insulating resin such as an epoxy resin, an acrylic resin, and a silicone resin, and in addition, an insulating resin containing a filler may be mentioned.

As illustrated in FIG. 2, the power supply member arrangement hole 54 is a substantially cylindrical hole that penetrates the base plate 50 and the bonding layer 60 in a vertical direction, and is provided so as not to penetrate the refrigerant flow path 52. An insulating tube 56 is stored in the power supply member arrangement hole 54. The insulating tube 56 is fixed to the power supply member arrangement hole 54 by an adhesive agent. An electrode terminal 26 electrically coupled to the electrostatic electrode 22 is exposed to the upper base of the power supply member arrangement hole 54. A power supply member 58 is electrically coupled to the electrode terminal 26. The power supply member 58 is obtained by connecting an upper metal terminal 58a and a lower metal terminal 58b by a flexible metal wire 58c, and the upper metal terminal 58a is bonded to the electrode terminal 26. The lower metal terminal 58b is exposed from the lower opening of the insulating tube 56, and coupled to the direct-current power supply 70 for electrostatic attraction. Note that the power supply member 58 may be a metal rod.

As illustrated in FIG. 2, the gas passage 24 is a substantially cylindrical hole that penetrates the base plate 50, the bonding layer 60 and the ceramic plate 20 in a vertical direction, and is provided so as not to penetrate the refrigerant flow path 52. The gas passage 24 is coupled to a He gas supply source 76. The gas passage 24 is provided from the lower surface of the base plate 50 to the wafer placement surface 21. Of the gas passage 24, the portion that penetrates the base plate 50 and the bonding layer 60 stores an insulating tube 57. The insulating tube 57 is fixed to the gas passage 24 by an adhesive agent. As illustrated in FIG. 3, the gas passage 24 penetrates the electrostatic electrode 22 and the heater electrode 30 in a vertical direction. The portion of the electrostatic electrode 22 through which the gas passage 24 passes, and the portion of the heater electrode 30 through which the gas passage 24 passes, are provided with through-holes 22a, 30a with a diameter greater than the diameter of the gas passage 24. Therefore, as illustrated in FIGS. 4 and 5, the electrostatic electrode 22 and the heater electrode 30 are not exposed to the inner wall of the gas passage 24.

Next, a method of manufacturing the ceramic plate 20 of the wafer placement table 10 will be briefly described. The ceramic plate 20 can be obtained such that e.g., three molding sheets are produced, each molding sheet is processed, then laminated and hot press fired, and subsequently, shape machining (such as hole drilling) is performed thereon. For example, the first molding sheet from the top is used as it is without being processed. For the second molding sheet from the top, a conductive paste is printed on the upper surface thereof so as to have the same shape as the electrostatic electrode 22. For the third molding sheet from the top, a conductive paste is printed on the upper surface thereof so as to have the same shape as the heater electrode 30. Each molding sheet can be produced by tape molding or mold cast molding. These three sheets are laminated, and hot press fired, and subsequently, shape machining (such as hole drilling) is performed thereon. Note that the gas passage 24 may be formed before the hot press firing, or formed after the hot press firing.

Next, a use example of thus configured wafer placement table 10 will be described. First, the wafer W is placed on the wafer placement surface 21 with the wafer placement table 10 installed in a chamber which is not illustrated. The inside of the chamber is depressurized by a vacuum pump, and adjusted to a predetermined degree of vacuum, and a direct-current voltage is applied to the electrostatic electrode 22 of the ceramic plate 20 to generate an electrostatic attraction force to cause the wafer W to be attracted and fixed to the wafer placement surface 21. He gas is supplied to the gas passage 24 from the He gas source 76. The He gas is filled in the space surrounded by the seal band 21a, the small circular projections 21b and the wafer W. Thus, heat transfer between the wafer W and the wafer placement surface 21 becomes favorable. Next, a reactive gas atmosphere having a predetermined pressure (e.g., several 10 to several 100 Pa) is created in the chamber, and in this state, a source voltage from the source power supply 72 and a bias voltage from the bias power supply 74 are applied to the base plate 50. A plasma is then generated between an upper electrode (not illustrated) provided in the ceiling portion in the chamber and the wafer placement surface 21 of the wafer placement table 10. The surface of the wafer W is treated by the generated plasma. Note that this treatment may be e.g., etching treatment using high-power plasma, such as deep etching. The temperature of the wafer W during a plasma treatment may be e.g., 50° C. to 90° C. A refrigerant is circulated through the refrigerant flow path 52 of the base plate 50 as appropriate. The set temperature of the refrigerant may be e.g., −70° C. to −30° C. In the deep etching, etching can be performed straight at a lower temperature, thus the etch rate can be increased.

Herein, during application of a bias voltage, an electric potential gradient from positive to negative in a vertical direction is generated in the internal space of the gas passage 24 along with application of a direct-current voltage to the electrostatic electrode 22, and application of a bias voltage to the base plate 50 which serves as a bias electrode. In this embodiment, during application of a bias voltage, a vertical electric potential gradient can be prevented from being generated between the electrostatic electrode 22 and the heater electrode 30 of the internal space of the gas passage 24 by electrically coupling the heater electrode 30 provided inside the ceramic plate 20 to the electrostatic electrode 22 so that the heater electrode 30 and the electrostatic electrode 22 have the same potential. Meanwhile, an electric potential gradient from positive to negative is generated between the heater electrode 30 and the base plate 50 serving as a bias electrode, but the vertical length over which an electric potential gradient is generated is approximately the same as the distance between the heater electrode 30 and the base plate 50, thus is short. Thus, when the heater electrode 30 and the electrostatic electrode 22 have the same potential during application of a bias voltage, even if electrons generated due to ionization of He atoms are accelerated and collide with other He atoms in the internal space of the gas passage 24, the distance for the acceleration is short, thus the electrons do not gain high energy, and even if the electrons collide with other He atoms, abnormal electrical discharge does not occur.

In contrast, when the heater electrode 30 provided inside the ceramic plate 20 cannot be electrically coupled to the electrostatic electrode 22 during application of a bias voltage, the vertical length over which an electric potential gradient is generated in the internal space of the gas passage 24 is longer than the distance in this embodiment. Thus, if electrons generated due to ionization of He atoms are accelerated and collide with other He atoms in the internal space of the gas passage 24, the distance for the acceleration is long, thus the electrons gain high energy, and those electrons collide with other He atoms, causing the He atoms to be ionized, further generating electrons, and this phenomenon is likely to occur repeatedly, therefore abnormal electrical discharge is likely to occur.

Note that even if a direct-current voltage is applied to the electrostatic electrode 22, when a bias voltage is not applied to the bias electrode, an electric potential gradient is small in the internal space of the gas passage 24. In this state, the electrons are not accelerated so much, thus abnormal electrical discharge is unlikely to occur. Therefore, in this case, the heater electrode 30 does not need to be coupled to the electrostatic electrode 22. In contrast, when plasma is not generated (normally, the bias voltage is not applied either), there is no heat input by plasma, thus the wafer W may be excessively cooled, and may be broken when transported later. In this embodiment, when plasma is not generated, the heater electrode 30 is coupled to the heater power supply 80 as necessary to generate heat, thus the wafer W can be maintained at or increased to a desired temperature. While the heater electrode 30 is being coupled to the heater power supply 80, an external refrigerant device may be halted, and circulation of refrigerant at a low temperature may be stopped. Note that the wafer W may be maintained at or increased to a desired temperature by switching the temperature of the refrigerant circulating through the refrigerant flow path 52 to a high temperature; however, using the heater electrode 30 allows the wafer W to be set to a desired temperature in a short time, which is preferable.

Switching of the coupling destination of the heater electrode 30 may be made by an operator operating the switcher 35, or a controller (not illustrated) coupled to the switcher 35 may control the switcher 35. The controller is comprised of a microprocessor including a CPU and a storage. The controller may also be coupled to the direct-current power supply 70 and the bias power supply 74, and may control the switcher 35 so that while a direct-current voltage is being applied to the electrostatic electrode 22 and a bias voltage is being applied to the bias electrode, the heater electrode 30 is electrically coupled to the electrostatic electrode 22.

In the wafer placement table 10 described in detail above, the heater electrode 30 is provided inside the ceramic plate 20 so as to be located in the periphery of each gas passage 24 under the electrostatic electrode 22 and not to be exposed to the inner wall of the gas passage 24. The switcher 35 is coupled to the heater electrode 30, and configured to switch between whether the heater electrode 30 is electrically coupled to the electrostatic electrode 22. The electrostatic electrode 22 has a positive potential when a direct-current voltage is applied thereto to attract the wafer W to the wafer placement surface 21. The base plate 50 serving as a bias electrode has a negative potential periodically when a bias voltage is applied thereto to draw ions in a plasma. Thus, during application of a bias voltage, a potential with a gradient from positive to negative in a vertical direction is generated in the internal space of the gas passage 24. When a heat transfer gas such as He gas is present in the gas passage 24, electrons ionized from He atoms are accelerated by an electric field, and collide with other unionized He atoms, which may cause arc discharge ultimately. In this embodiment, the vertical distance over which an electric potential gradient is generated can be reduced by electrically coupling the heater electrode 30 provided under the electrostatic electrode 22 to the electrostatic electrode 22 so that the heater electrode 30 and the electrostatic electrode 22 have the same potential. As a result, even if electrons ionized from He atoms are produced, those electrons are not sufficiently accelerated by an electric potential gradient, and do not gain sufficient energy, thus occurrence of arc discharge can be avoided. Therefore, occurrence of abnormal electrical discharge in each passage 24 can be prevented or reduced. When the heater electrode 30 does not need to have the same potential as the electrostatic electrode 22, such as when a bias voltage is not applied, the heater electrode 30 can be electrically separated from the electrostatic electrode 22.

The switcher 35 is configured to switch between whether the heater electrode 30 is electrically coupled to the electrostatic electrode 22 or the heater power supply 80. When a bias voltage or a source voltage is not applied, there is no chance of occurrence of electrical discharge, and on the other hand, the wafer may be excessively cooled, but the wafer W can be maintained at or increased to a desired temperature by coupling the heater electrode 30 to the heater power supply 80 to generate heat.

Furthermore, in the periphery of each gas passage 24, the heater electrode 30 is branched and merged so as to surround the gas passage 24. In this manner, the heater electrode 30 surrounds the periphery of the gas passage 24 full circle without a gap, thus when the heater electrode 30 is electrically coupled to the electrostatic electrode 22, variation in the electrical potential distribution can be prevented in a circumferential direction of the gas passage 24.

Furthermore, the base plate 50 also serves as a bias electrode. Therefore, it is not necessary to provide a bias electrode separately from the base plate 50.

The gas passage 24 is coupled to the He gas source 76. Thus, in the internal space of the gas passage 24, the following phenomenon is likely to occur: He atoms are ionized, producing electrons which collide with other He atoms, thus application of the present invention has high significance.

In addition, the base plate 50 also serves as a source electrode. Therefore, it is not necessary to provide a source electrode separately from the base plate 50.

Note that the present invention is not limited to the above-described embodiment at all, and it is needless to say that the present invention can be carried out in various forms as long as the forms belong to the technical scope of the present invention.

In the above-described embodiment, the base plate 50 also serves as a bias electrode; however, a bias electrode may be built in the ceramic plate 20.

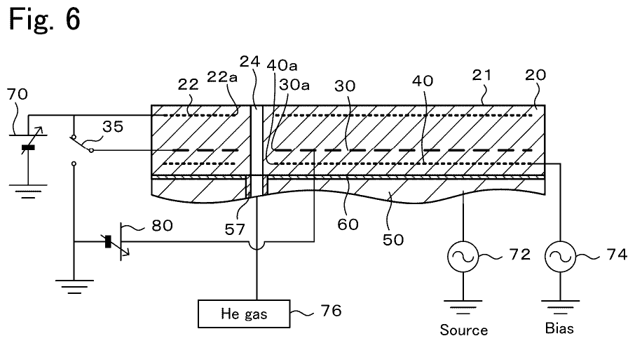

For instance, in FIG. 6, as an example of a bias electrode built in the ceramic plate 20, an example is illustrated in which a bias electrode 40 is provided under the heater electrode 30 of the above-described embodiment. In FIG. 6, the same components as in the above-described embodiment are labeled with the same symbol. The bias electrode 40 is a planar mesh electrode having substantially the same shape as the electrostatic electrode 22. The bias electrode 40 is neither electrically coupled to the electrostatic electrode 22 nor the heater electrode 30, but is coupled to the bias power supply 74. The portion of the bias electrode 40 through which the gas passage 24 passes is provided with a through-hole 40a with a diameter greater than the diameter of the gas passage 24. Therefore, the bias electrode 40 is not exposed to the inner wall of the gas passage 24. Also, in the case of FIG. 6, the same effect as in the above-described embodiment is obtained. Note that when bias RF generated by the bias power supply 74 is a rectangular wave, from the viewpoint of protection of the source power supply 72, the bias electrode is preferably independent from the source electrode. Thus, when the bias RF is a rectangular wave, it is more preferable to build in the bias electrode 40 in the ceramic plate 20 than to use the base plate 50, which also serves as a source electrode, as a bias electrode. In the case of FIG. 6, the bias electrode can be brought close to the wafer placement surface 21, thus the time constant for the transient response can be reduced.

When the bias electrode is built in the ceramic plate 20, the outer circumference of the bias electrode 40 may be provided with an outer bias electrode which is electrically independent from the bias electrode. Although illustration of the outer bias electrode is omitted, the outer bias electrode is a ring-shaped electrode provided on the same plane as the circular bias electrode 40, and is not electrically coupled to any of the electrostatic electrode 22, the heater electrode 30, or the bias electrode 40. In this setting, different bias voltages can be applied to the bias electrode 40 and the outer bias electrode. Thus, the degree of attraction of ions can be changed between the central side and the outer circumferential side of the wafer W. Note that when a focus ring is placed on a step portion provided along the outer circumference of the ceramic plate 20, the degree of attraction of ions can be changed between the focus ring and the wafer W.

In the above-described embodiment, the switcher 35 is configured to switch between whether the heater electrode 30 is electrically coupled to the electrostatic electrode 22 or the heater power supply 80, but is not limited thereto. For example, the switcher 35 may be configured to switch between whether the heater electrode 30 is electrically coupled to the electrostatic electrode 22 or the heater power supply 80, or set to an off state without being coupled to various power supplies and the like.

Alternatively, for example, the switcher 35 may be configured to switch between whether the heater electrode 30 is electrically coupled to the electrostatic electrode 22 or set to an off state without being coupled to various power supplies and the like. In this setting, electrical power consumption can be reduced by setting the heater electrode 30 to an off state as appropriate.

In the above-described embodiment, the heater electrode 30 is provided as an internal electrode, but is not limited thereto. For example, the internal electrode may not have the function as a heater electrode (may not be coupled to the heater power supply 80), but may have the function as an electric potential gradient adjustment electrode, or may have another function.

In the above-described embodiment, the heater electrode 30 has the parallel sections 32; however, the heater electrode 30 does not need to have the parallel sections 32 if the heater electrode 30 is located in the periphery of the gas passage 24, and not exposed to the inner wall of the gas passage 24.

In the above-described embodiment, the heater electrode 30 is wired from one terminal 31a of a pair of terminals 31 to the other terminal 31b so as to cover substantially the entire area of the ceramic plate 20, but is not limited thereto. For example, the ceramic plate 20 is divided into a plurality of small zones, and the heater electrode 30 may be wired in each small zone. In this case, each heater electrode 30 starts from one terminal 31a of a pair of terminals 31, and is wired on substantially the entire area of the small zone, then reaches the other terminal 31b of the pair of terminals 31. The small zones may be e.g., circular or annular zones divided by boundaries concentric to the ceramic plate 20, or may be sector-shaped zones divided by line segments radially extending from the center of the ceramic plate 20. Note that when a plurality of heater electrodes 30 are provided, all heater electrodes 30 may be coupled to an individual or common switcher 35, or only those heater electrodes 30 disposed in the periphery of the gas passage 24 may be coupled to an individual or common switcher 35.

In the above-described embodiment, one-layer heater electrode 30 is provided, but two or more layers of the heater electrode 30 may be provided. In this case, the switcher 35 may be coupled to at least one layer of the heater electrode 30, and the switcher 35 is preferably coupled to at least the lowermost layer of the heater electrode 30. The vertical distance over which an electric potential gradient is generated can be further reduced by coupling the switcher 35 to the lowermost layer of the heater electrode 30. When the switcher 35 is coupled to each of all heater electrodes 30, the electrical potential distribution in the gas passage 24 becomes more favorable. When two or more layers of the heater electrode 30 are provided, the switcher 35 may be directly connected to each heater electrode 30. Alternatively, two or more layers of the heater electrode 30 may be connected by a vertically extending via, and the switcher 35 may be directly connected to one of the layers of the heater electrode 30 and indirectly connected to the other layers of the heater electrodes 30 through the via. Note that part of the two or more layers of the internal electrode may be heater electrode 30, and the remaining may be electrodes other than the heater electrode 30, or all of the two or more layers of the heater electrode 30 may be electrodes other than the heater electrode 30.

In the above-described embodiment, a portion of the gas passage 24, where an electrical potential distribution occurs may be provided with a porous plug (a plug allowing a vertical gas flow). Alternatively, a compact plug having a zigzag or swirl passage (a passage allowing a vertical gas flow) may be adopted instead of a porous plug. In this setting, occurrence of abnormal electrical discharge at a portion where an electrical potential distribution occurs is more likely to be prevented.

In the above-described embodiment, the case has been illustrated in which three gas passages 24 are provided, but the number of gas passages 24 is not limited to three, and may be any number. The gas passage 24 is a passage that penetrates the wafer placement table 10 in a vertical direction, but is not limited to thereto. For example, instead of the gas passage 24, a gas channel structure may be adopted. As the gas channel structure, a structure may be adopted which includes: a ring-shaped passage provided inside the base plate 50 and concentric to the base plate 50 in a plan view; a gas inlet passage for introducing gas from the lower surface of the base plate 50 to the ring-shaped passage; and a plurality of gas distribution passages extending upward from the ring-shaped passage and open to the wafer placement surface 21. The number of gas inlet passages may be smaller than the number of gas distribution passages, for example, may be one. Such a gas channel structure also corresponds to a “passage” of the present invention.

In the above-described embodiment, a lift pin hole may be provided separately from the gas passage 24. The lift pin hole is a hole that penetrates the wafer placement table 10 in a vertical direction for inserting a lift pin to vertically move the wafer W with respect to the wafer placement surface 21. For example, when the wafer W is supported by three lift pins, three lift pin holes are provided. The configuration of the lift pin hole and its periphery is similar to the configuration of the gas passage 24 and its periphery. The lift pin hole is provided from the lower surface of the ceramic plate 20 to the wafer placement surface 21. Thus, although He gas also enters the lift pin hole, as in the gas passage 24, occurrence of abnormal electrical discharge in the lift pin hole can be prevented or reduced. Such a lift pin hole also corresponds to a “passage” of the present invention.

International Application No. PCT/JP2023/039550, filed on Nov. 2, 2023, is incorporated herein by reference in its entirety.

What is claimed is:

1. A member for semiconductor manufacturing apparatus, comprising:
a ceramic plate having a wafer placement surface on its upper surface and a built-in electrostatic electrode;
a base plate provided on a lower surface of the ceramic plate, and configured to include a built-in refrigerant flow path;
a passage provided from a lower surface of the base plate to the wafer placement surface of the ceramic plate;
an internal electrode provided inside the ceramic plate so as to be located in a periphery of the passage under the electrostatic electrode and not to be exposed to an inner wall of the passage;
a switcher coupled to the internal electrode, and configured to switch between whether the internal electrode is electrically coupled to the electrostatic electrode; and
a bias electrode provided at a height lower than or equal to a height of the internal electrode electrically independently from the electrostatic electrode, and configured to receive application of a bias voltage when plasma is generated over the wafer placement surface.

2. The member for semiconductor manufacturing apparatus according to claim 1,
wherein the internal electrode is a heater electrode to be coupled to a heater power supply to generate heat, and
the switcher is configured to switch between whether the heater electrode is electrically coupled to the electrostatic electrode or the heater power supply.

3. The member for semiconductor manufacturing apparatus according to claim 2,
wherein the heater electrode is wired from one of a pair of terminals to the other of the pair of terminals, and in a periphery of the passage, the heater electrode is located surrounding the passage, branched and merged.

4. The member for semiconductor manufacturing apparatus according to claim 3,
wherein the heater electrode forms a parallel circuit in the periphery of the passage.

5. The member for semiconductor manufacturing apparatus according to claim 1,
wherein the base plate also serves as the bias electrode.

6. The member for semiconductor manufacturing apparatus according to claim 1,
wherein the bias electrode is built in the ceramic plate.

7. The member for semiconductor manufacturing apparatus according to claim 1,
wherein the passage is coupled to a supply source of heat transfer gas.

8. The member for semiconductor manufacturing apparatus according to claim 1,
wherein the base plate also serves as a source electrode that, when plasma is generated over the wafer placement surface, receives application of a source voltage.
